(19) United States
(12) Patent Application Publication
(10) Pub. No.: US 2013/0069092 A1
(43) Pub. Date: Mar. 21, 2013

(54) LIGHT-EMITTING DIODE AND METHOD MANUFACTURING THE SAME

(71) Applicants: PIN-CHUAN CHEN, Hsinchu (TW); HSIN-CHIANG LIN, Hsinchu (TW)

(72) Inventors: PIN-CHUAN CHEN, Hsinchu (TW); HSIN-CHIANG LIN, Hsinchu (TW)

(73) Assignee: ADVANCED OPTOELECTRONIC TECHNOLOGY, INC., Hsinchu Hsien (TW)

(21) Appl. No.: 13/414,726

(22) Filed: Mar. 8, 2012

(30) Foreign Application Priority Data
Sep. 19, 2011 (CN) 201110277572.0

(51) Int. Cl. H01L 33/60

(52) U.S. Cl. 257/98; 438/27; 257/E33.072

(57) ABSTRACT

An LED includes a base, first and second electrodes embedded in the base, and an LED chip electrically connected with the first and second electrodes. The first electrode includes a first main body portion and three first branch portions. The second electrode includes a second main body and three second branch portions. The first and second branch portions are exposed at sidewalls of the base. One of the first branch portions and one of the second branch portions are exposed at two opposite lateral sides of the base respectively, and another one of the first branch portions and another one of the second branch portions are exposed at the same lateral side of the base. This disclosure also discloses a manufacture method for making the LED.

### BACKGROUND

1. Technical Field

The present disclosure generally relates to semiconducting illumination, and particularly to a light-emitting diode (LED) and a method manufacturing the LED.

2. Description of Related Art

With developments in semiconducting technology, LEDs, which are new generation light-emitting devices, are widely used as illuminating light sources instead of the cold cathode fluorescent lamps (CCFLs) and incandescent lamp due to their high light-emitting efficiencies, high brightness and long lifespan.

A typical LED includes a base, two electrodes mounted on the base, a light-emitting chip electrically connected to the two electrodes, and an encapsulant covering the light-emitting chip. The two electrodes respectively extend beyond two opposite sides of the base towards a bottom surface of the base, in order that the LED can be mounted on a circuit board with its bottom surface adhered on the circuit board. However, this causes an inferior mounting adaptability to the LED.

What is needed, therefore, is an LED which can overcome the limitations described.

### BRIEF DESCRIPTION OF THE DRAWINGS

FIG. 1 is a top view of a light-emitting diode in accordance with a first embodiment of the present disclosure.

FIG. 2 is a cross sectional view of the light-emitting diode of FIG. 1, taken along line II-II thereof.

FIG. 3 is a cross sectional view of the light-emitting diode of FIG. 1, taken along line thereof.

FIG. 4 is a cross sectional view of the light-emitting diode of FIG. 1, taken along line IV-IV thereof.

FIG. 5 is a bottom view of the light-emitting diode of FIG. 1.

FIG. 6 is a schematic view of a light-emitting diode in accordance with a second embodiment of the present disclosure.

FIG. 7 is a bottom view of the light-emitting diode of FIG. 6.

FIG. 8 is a top view of a light-emitting diode in accordance with a third embodiment of the present disclosure.

FIG. 9 is a schematic view showing a first step of a method for manufacturing a light-emitting diode of the present disclosure.

FIG. 10 is a schematic view showing a second step of the method for manufacturing a light-emitting diode of the present disclosure.

FIG. 11 is a schematic view showing a third step of the method for manufacturing a light-emitting diode of the present disclosure.

FIG. 12 is a schematic view showing a fourth step of the method for manufacturing a light-emitting diode of the present disclosure.

### DETAILED DESCRIPTION

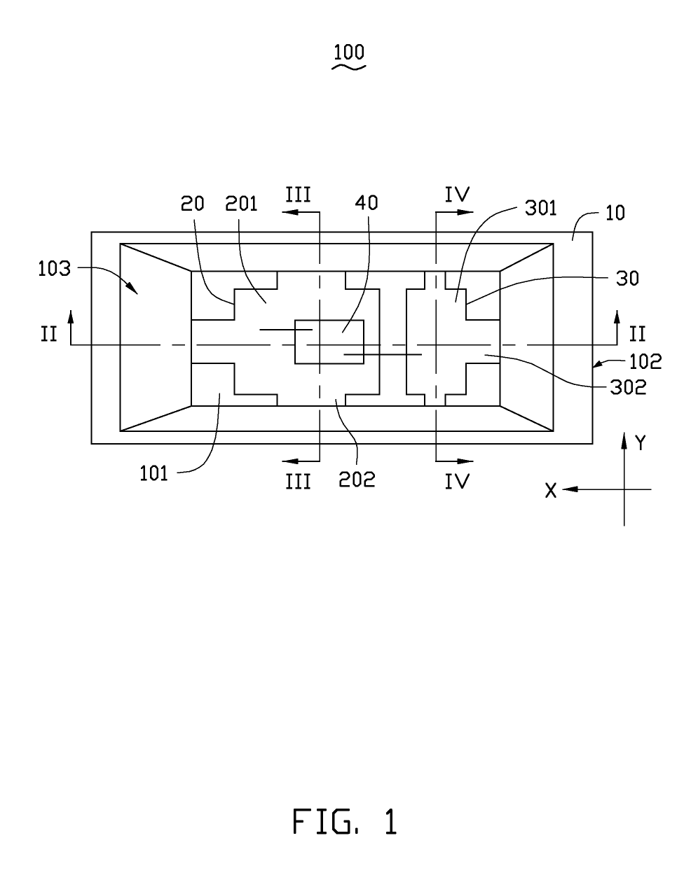

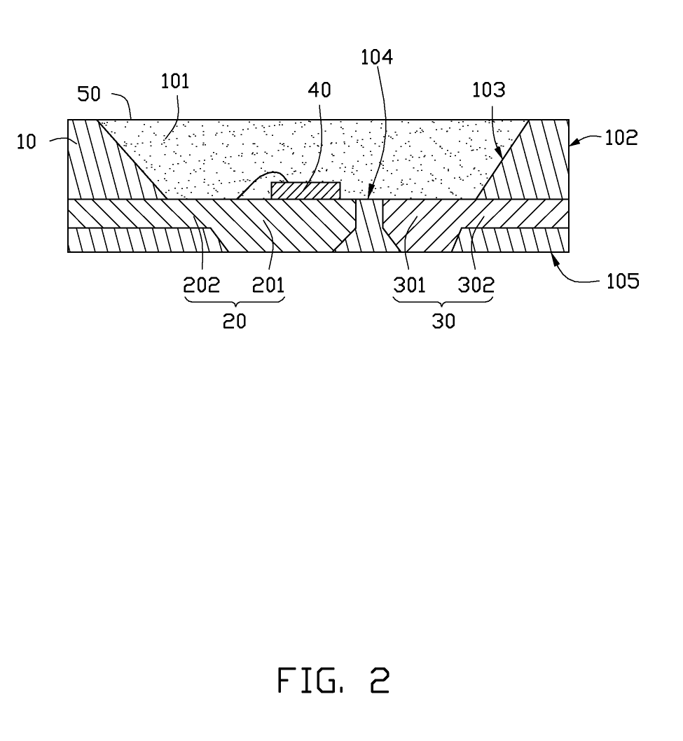

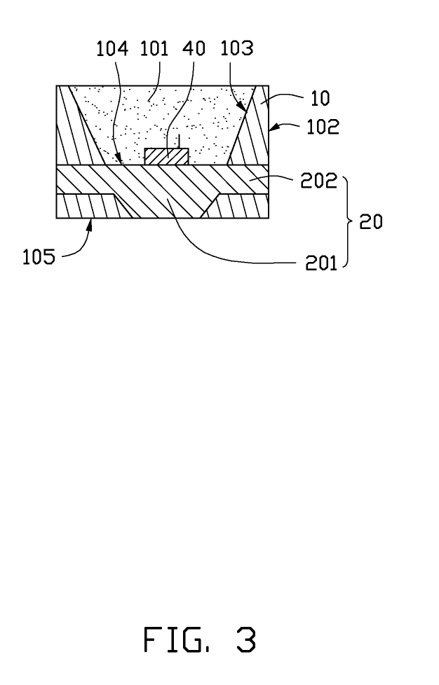

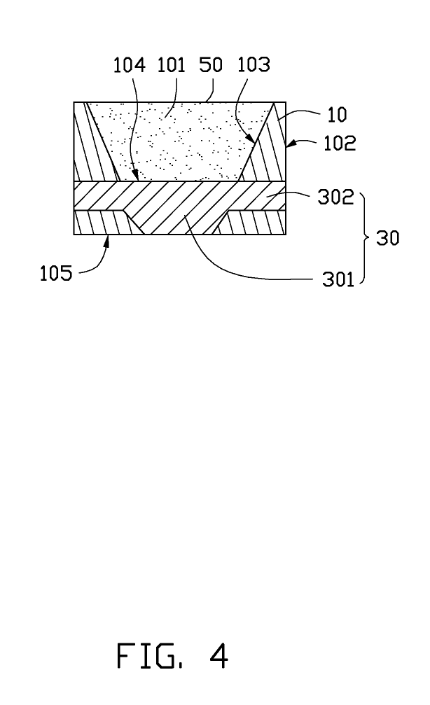

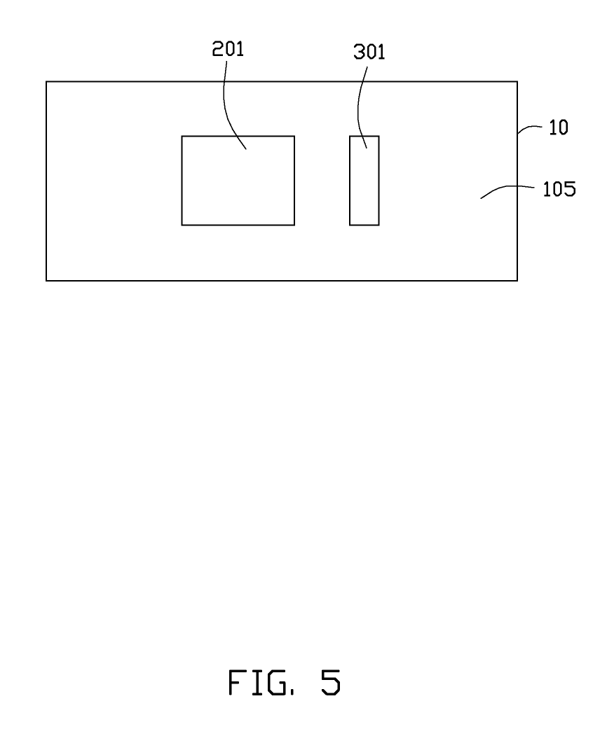

Referring FIGS. 1 to 5, an LED 100 in accordance with a first embodiment of the present disclosure is shown. The LED 100 includes a base 10, a first electrode 20 and a second electrode 30 embedded in the base 10, and an LED chip 40.

The base 10 is rectangular and defines a recess 101 therein. The base 10 includes four outer sidewalls 102, four inner sidewalls 103, an inner bottom wall 104 and an outer bottom wall 105. The four inner sidewalls 103 and the inner bottom wall 104 cooperatively define the recess 101. The four inner sidewalls 103 are slantwise, surround the recess 101 and extend outwardly and upwardly from a peripheral portion of the inner bottom wall 104. The inner bottom wall 104 is located at a bottom of the recess 101. The LED chip 40 is mounted on the inner bottom wall 104. The base 10 is made of light reflecting materials, such as epoxy resin, silicone, polyphthalamide (PPA), et al. The four outer sidewalls 102 face an outside of the base 10. The four inner sidewalls 103 are able to reflect light and slantwise face the LED chip 40.

An encapsulant 50 is received in the recess 101. The encapsulant 50 covers the first electrode 20, the second electrode 30 and the LED chip 40. The encapsulant 50 is made of transparent and heat-resistant material, such as epoxy, glass, etc. The encapsulant 50 is doped with at least one kind of fluorescence powder. In other embodiment, the encapsulant 50 can be provided with a fluorescence layer on a top surface thereof.

The first electrode 20 and the second electrode 30 both are embedded in the base 10, each having a top surface coextensive with the inner bottom wall 104. The first and second electrodes 20, 30 are electrically insulating from each other. The first electrode 20 is substantially T-shaped. The first electrode 20 includes a first main body portion 201 and three first branch portions 202 extending outwardly from the first main body portion 201. The first main body portion 201 is substantially rectangular. The three first branch portions 202 respectively extend from three sides of the first main body portion 201. The side of the main body portion 201 without the first branch portions 202 faces the second electrode 30. A thickness of the first main body portion 201 is larger than that of each of the first branch portions 202. The first main body portion 201 is inverted trapezoidal and extends from the inner bottom wall 104 to the outer bottom wall 105. The first main body portion 201 is exposed both at the inner bottom wall 104 and the outer bottom wall 105. The three first branch portions 202 of the first electrode 20 respectively extend through three outer sidewalls 102 of the base 10 along three different directions around the base 10. A free end of each first branch portion 202 is exposed at a corresponding outer sidewall 102.

The second electrode 30 is similar to the first electrode 20 and includes a second main body portion 301 and three second branch portions 302 respectively extending outwardly from three sides of the second main body portion 301. The second electrode 30 differs from the first electrode 20 in that the second main body portion 301 of the second electrode 30 has a smaller size than that of the first main body portion 201 of the first electrode 20.

The first main body portion 201 of the first electrode 20 is spaced from the second main body portion 301 of the second electrode 30. One of the first branch portions 202 of the first electrode 20 and one of the second branch portions 302 of the second electrode 30 respectively extend along two opposite directions of an X axis (referring to FIG. 1). The other two of the first branch portions 202 of the first electrode 20 extend respectively along two opposite directions of a Y axis (referring to FIG. 1) perpendicular to the X axis, and the other two of the second branch portions 302 of the second electrode 30 also extend respectively along the two opposite directions of the Y axis.

The LED chip 40 is positioned on the first main body portion 201 of the first electrode 20. Two electrical contacts (not labeled) of the LED chip 40 are respectively electrically connected to the first main body portion 201 of the first electrode 20 and the second main body portion 301 of the second electrode 30 through wire bonding. In other embodiment, the two electrical contacts of the LED chip 40 can be electrically connected to the first and second electrodes 20, 30 through flip chip bonding or eutectic bonding.

When the LED 100 is mounted on a circuit board, the first main body portion 201 or each of the first branch portions 202 of the first electrode 20 can match with the second main body portion 301 or a corresponding second branch portion 302 of the second electrode 30 to be paired to enable the LED 100 to be mounted on the circuit board in different ways and different configurations. For example, the first main body portion 201 of the first electrode 20 matching with the second main body portion 301 of the second electrode 30 enables the LED 100 to be mounted on the circuit board with its outer bottom wall 105 abutting against the circuit board. A first branch portion 202 of the first electrode 20 matching with a second branch portion 302 of the second electrode 30 at a same outer sidewall 102 enables the LED 100 to be mounted on the circuit board with the outer sidewall 102 abutting against the circuit board. Thus, the LED 100 of the present disclosure has better mounting adaptability than the LED in accordance with prior art.

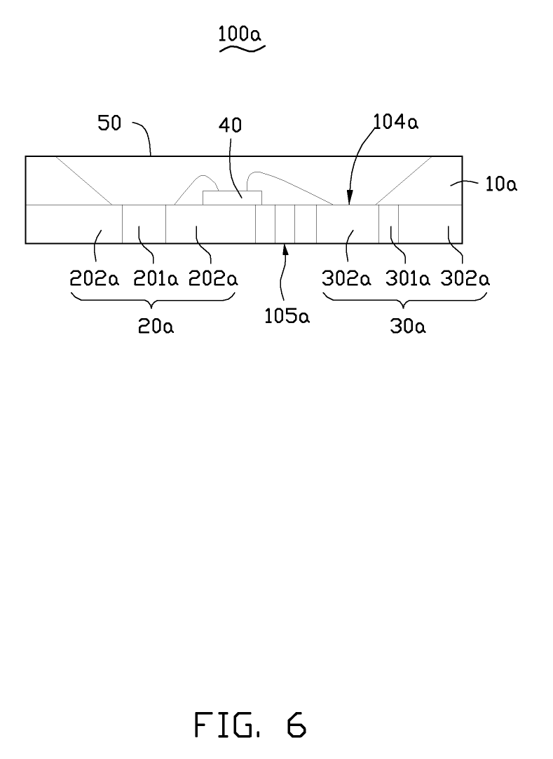

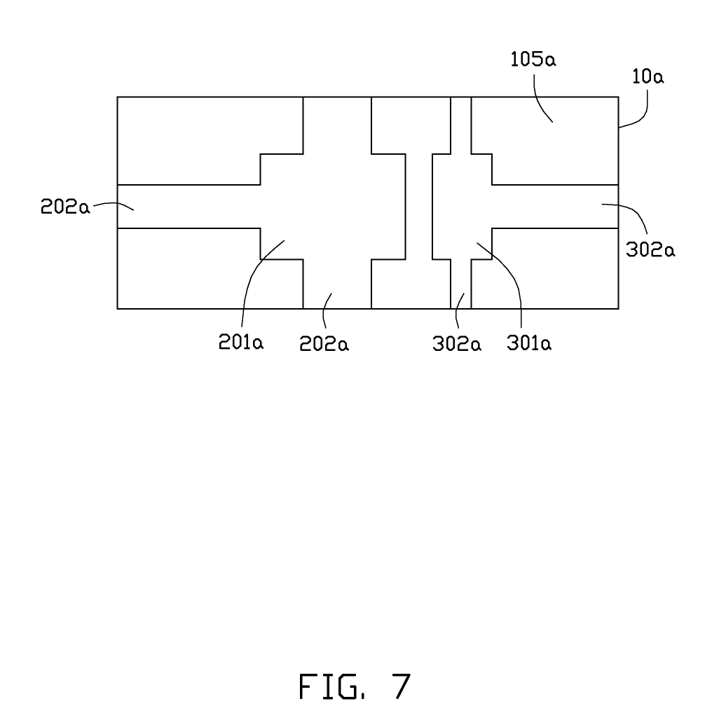

FIGS. 6 and 7 illustrate an LED 100a in accordance with a second embodiment of the present disclosure. The LED 100a is similar to that of the first embodiment but differs from that of the first embodiment in first electrode 20a and second electrode 30a. The first electrode 20a of the LED 100a includes a first main body portion 201a and three first branch portions 202a extending from three lateral sides of the first main body portion 201a, respectively. The first main body portion 201a has a thickness equal to that of the first branch portions 202a. The first main body portion 201a and the first branch portions 202a are exposed at the inner bottom wall 104a and the outer bottom wall 105a of the base 10a of the LED 100. The second electrode 30a of the LED 100a includes a second main body portion 301a and three second branch portions 302a extending from three lateral sides of the second main body portion 301a, respectively. The second main body portion 301a has a thickness equal to that of the second branch portions 302a. The second main body portion 301a and the second branch portions 302a are exposed at the inner bottom wall 104a and the outer bottom wall 105a of the base 10a of the LED 100a. Thus, the first branch portions 202a and the second branch portions 302a have an increased area for current flowing therethrough.

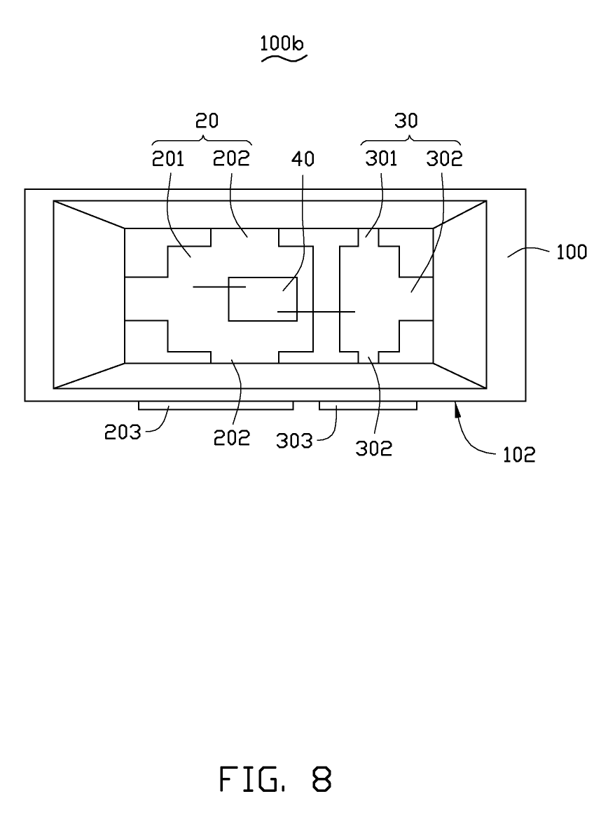

FIG. 8 illustrates an LED 100b in accordance with a third embodiment of the present disclosure. The LED 100b is similar to that of the first embodiment but differs from that of the first embodiment in that a first extending electrode 203 and a second extending electrode 303 are formed on an outer sidewall 102 at which a first branch portion 202 of the first electrode 20 and a second branch portion 302 of the second electrode 30 are exposed. The first/second extending electrode 203/303 increases an area of the first/second electrode 20/30 for current flowing therethrough. In other embodiment, the first/second extending electrode 203/303 can be formed on other out sidewalls 102 at which the first/second branch portion 202/302 of the first/second electrode 20/30 are exposed.

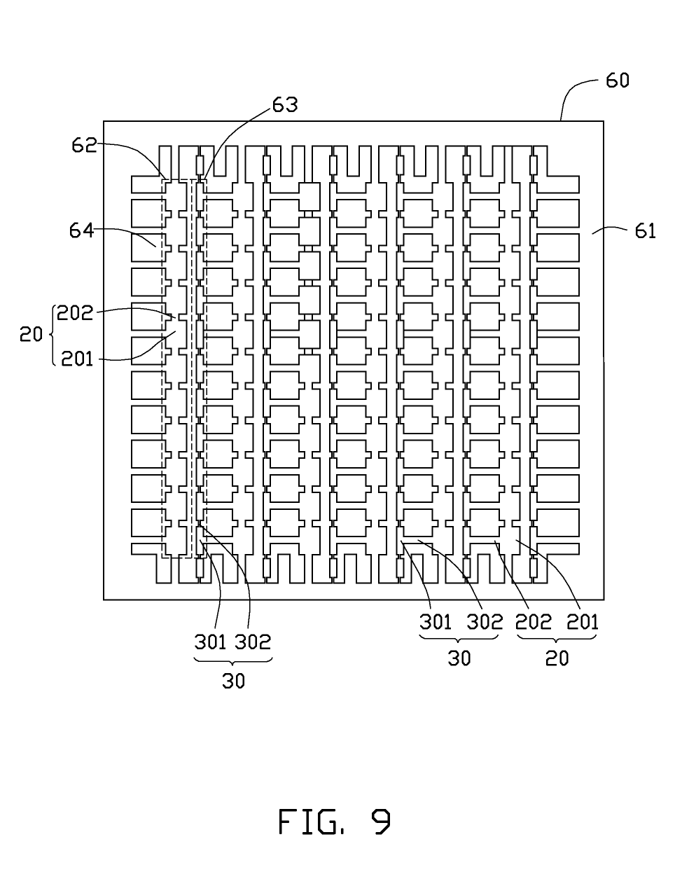

A method for manufacturing an LED, taking the LED 100 for example, is also disclosed hereinafter. Referring to FIGS. 9 to 12, the method mainly includes a series of steps as follows.

First, an electric-conducting base plate 60 is provided as shown in FIG. 9. The base plate 60 is made of electrically conductive material such as gold, copper, aluminum, etc. The base plate 60 is flat and rectangular. A frame 61, a plurality of first electrode columns 62 and a plurality of second electrode columns 63 are formed on the base plate 60 through etching. Alternatively, in other embodiment, the first electrode column 62 and the second electrode column 63 can be formed on the base plate 60 through stamping or other mechanical processing methods. The frame 61 is hollow and rectangular. The frame 61 surrounds the first electrode columns 62 and the second electrode columns 63. The number of the first electrode columns 62 is equal to that of the second electrode columns 63. The first electrode columns 62 and the second electrode columns 63 are spaced from each other and alternately arranged. A plurality of hollow zones 64 are defined between each first electrode column 62 and an adjacent second electrode column 63, and a plurality of hollow zones 64 are defined between the first/second electrode column 62/63 and the frame 61.

Each of the first electrode columns 62 includes a plurality of first electrodes 20 arranged in a line. The first main body portions 201 of the first electrodes 20 of each first electrode column 62 are connected with each other through the first branch portions 202 of the first electrodes 20. Two first electrodes 20 at opposite top and bottom ends of each first electrode column 62 are respectively connected with opposite top and bottom sides of the frame 61 through two first branch portions 202 thereof. Each of the second electrode columns 63 includes a plurality of second electrodes 30 arranged in a line. The second main body portions 301 of the second electrodes 30 of each second electrode column 63 are connected with each other by the second branch portions 302 of the second electrodes 30. Two second electrodes 30 at two opposite ends of each second electrode column 63 are connected with the top and bottom sides of the frame 61 through two second branch portions 302 thereof.

An outmost first electrode column 62 and an outmost second electrode column 63 are respectively adjacent to two opposite lateral sides of the frame 61. The first main body portions 201 of the outmost first electrode column 62 are connected with one of the two opposite lateral sides of the frame 61 through the first branch portions 202 thereof. The second main body portions 301 of the outmost second electrode column 63 are connected with the other one of the two opposite lateral sides of the frame 61 through the second branch portions 302 thereof. The first and second electrode columns 62, 63 between the outmost first electrode column 62 and the outmost second electrode column 63 are grouped into a plurality of (i.e., five) separate pairs each including a corresponding first electrode column 62 and a corresponding second electrode column 63, wherein the first and second electrodes 20, 30 in each pair are connected together via the branch portions 202/302. From another aspect, as viewed from FIG. 9, the first electrodes 20 in each first electrode column 62 other than the outmost first electrode column 62 are connected with the second electrodes 30 in the neighboring left second electrode column 63 via the branch portions 202 and separated from the second electrodes 30 in the neighboring right second electrode column 63.

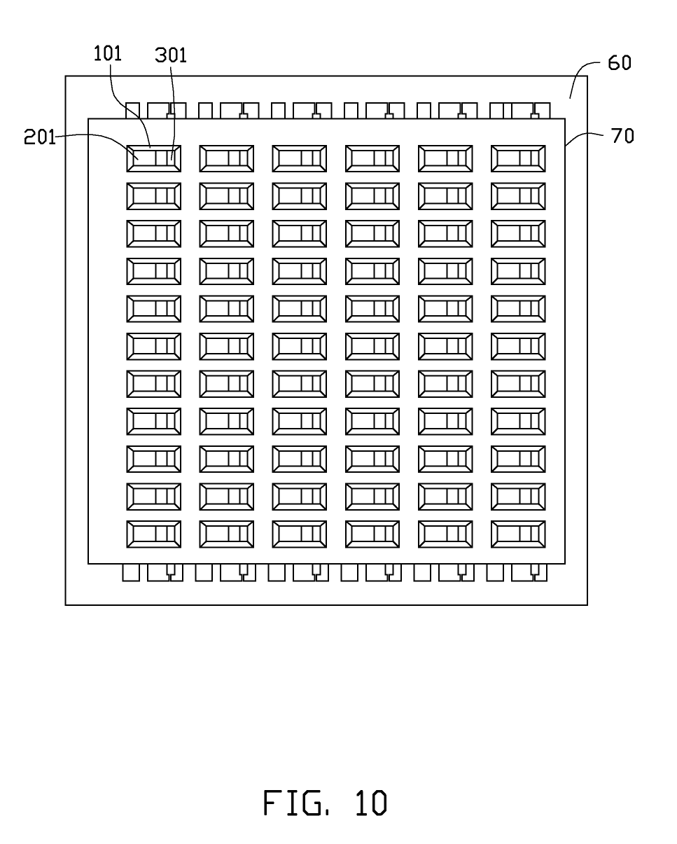

As shown in FIG. 10, a substrate plate 70 is then formed on the base plate 60. The substrate plate 70 is formed on the base plate 60 through molding. The substrate plate 70 is made of light reflecting material such as epoxy resin, silicone, polyphthalamide (PPA), etc. The first electrode columns 62 and the second electrode columns 63 are embedded in the substrate plate 70. Both the first main body portion 201 of each of the first electrodes 20 and the second main body portion 301 of each of the second electrodes 30 are exposed at opposite top and bottom sides of the substrate plate 70. The substrate plate 70 defines a plurality of recesses 101 therein, each of which corresponding to one of the first electrodes 20 and a neighboring second electrode 30. The corresponding first electrode 20 and the corresponding second electrode 30 are located at a bottom of each of the recesses 101.

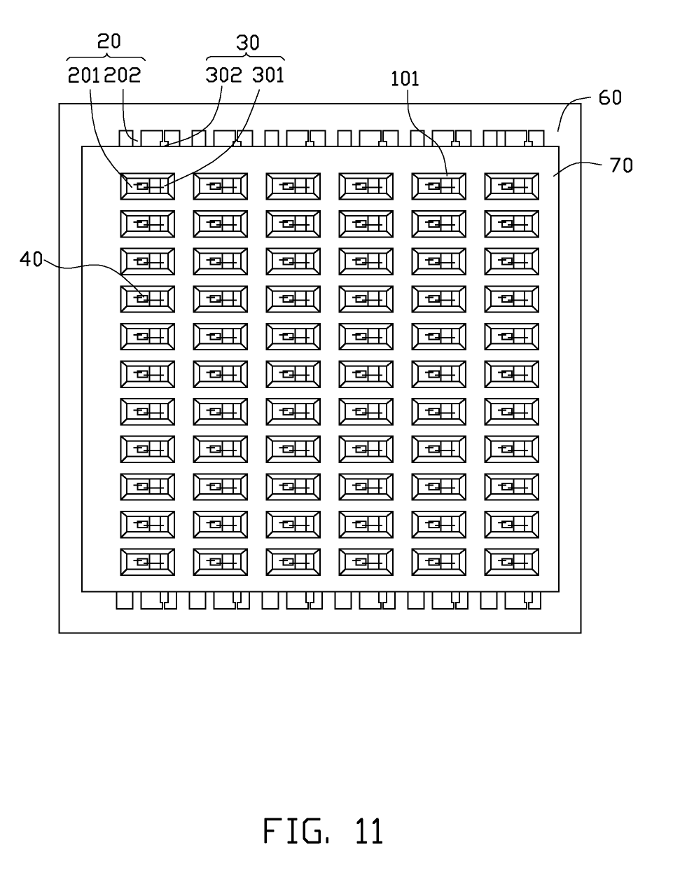

Referring to FIG. 11, an LED chip 40 then is mounted on the first main body portion 201 of each of the first electrodes 20 of each first electrode column 62 with two electrical contacts thereof electrically connected to the first main body portion 201 and the second main body portion 301 of the second electrode 30 through wire bonding, respectively. In other embodiment, the two electrical contacts of the LED chip 40 can be electrically connected to the first and second electrodes 20, 30 through flip chip bonding or eutectic bonding.

Then the encapsulant 50 is formed in each of the recesses 101 of the substrate plate 70 through injection or molding.

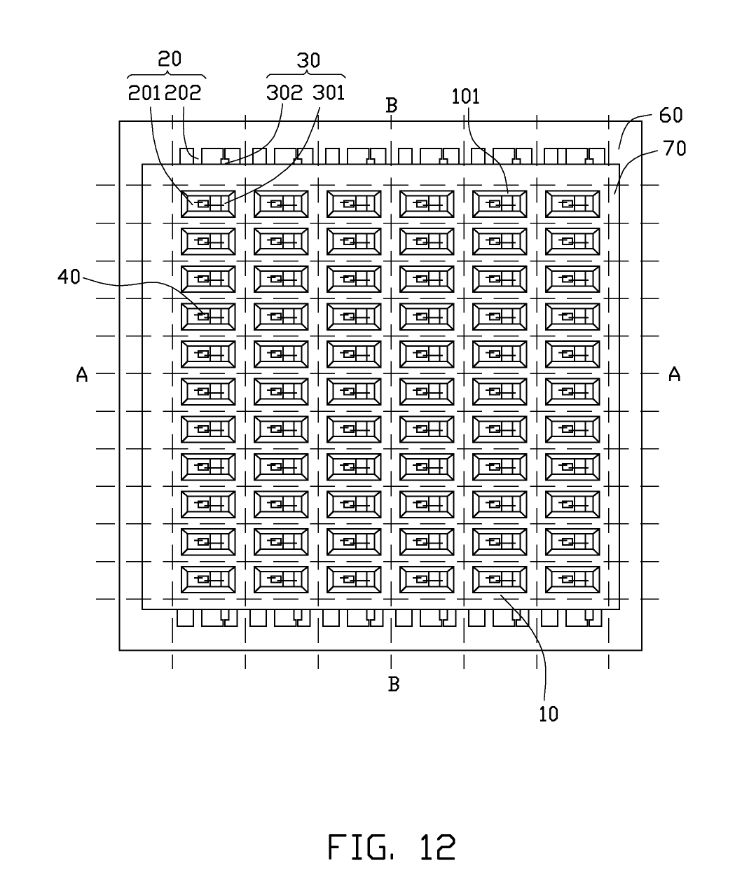

Finally, referring to FIG. 12, the substrate plate 70 and the base plate 60 are cut into a plurality of the pieces along widthwise lines A-A and lengthwise lines B-B thereof respectively. The widthwise lines A-A are perpendicular to the first/second electrode columns 62/63. The lengthwise lines B-B are parallel to the first/second electrode columns 62/63. The first/second branch portions 202/302 between two adjacent first/second main body portions 201/301 in each first/second electrode column 62/63 are cut off during the widthwise cuttings. Each first/second electrode column 62/63 and an adjacent second/first electrode column 63/62 of a corresponding pair which originally connect with each other are separated from each other during the lengthwise cuttings. In this state, each first electrode 20 of a first electrode column 62 and a corresponding second electrode 30 of an adjacent second electrode column 63 which are originally spaced from each other are formed as the electrodes for a corresponding LED 100. The substrate plate 70 is cut into a plurality of bases 10. The base 10, the first electrode 20 and the second electrode 30 received in the base 10, and the LED chip 40 mounted on the first electrode cooperatively compose the LED 100 in the first embodiment.

The LED 100a also can be manufactured through this method. A method for manufacturing the LED 100b is similar to the method for manufacturing the LED 100/100a, but further includes a step for providing a first/second extending electrode 203/303 at a free end of a first/second branch portion 202/302 of the first/second electrode 20/30 after the cutting step.

It is to be understood, however, that even though numerous characteristics and advantages of the exemplary embodiments have been set forth in the foregoing description, together with details of the structures and functions of the embodiments, the disclosure is illustrative only; and that changes may be made in detail, especially in matters of shape, size, and arrangement of parts within the principles of the embodiments to the full extent indicated by the broad general meaning of the terms in which the appended claims are expressed.

What is claimed is:

1. An LED comprising:
a base;
a first electrode and a second electrode embedded in the base, the first electrode comprising a first main body portion and a plurality of first branch portions extending from the first main body portion along different directions, respectively, the second electrode comprising a second main body portion and a plurality of second branch portions extending from the second main body portion along different directions, respectively, free ends of the first branch portions and the second branch portions exposed at sidewalls of the base, at least one of the first branch portions and at least one of the second branch portions appearing at two opposite sidewalls of the base respectively, and at least another one the first branch portions and at least another one of the second branch portions appearing at a same sidewall of the base; and
an LED chip electrically connected to the two electrodes.

2. The LED of claim 1, wherein the base comprises an inner bottom wall and an outer bottom wall, and the first main body portion and the second main body portion both are exposed at the inner bottom wall and the outer bottom wall.

3. The LED of claim 2, wherein the first branch portions and the second branch portions are exposed at the inner bottom wall and the outer bottom wall.

4. The LED of claim 2, wherein the base further comprises a plurality of inner sidewalls and outer sidewalls, the base defines a recess therein, the inner bottom wall is positioned at a bottom of the recess, the inner sidewalls surround the recess and extend outwardly and upwardly from a periphery of the inner bottom wall, and the first branch portions of the first electrode and the second branch portions of the second electrode run through the outer sidewalls respectively and are exposed at the outer sidewalls respectively.

5. The LED of claim 4, wherein the second main body portion of the second electrode has a smaller size than the first main body portion of the first electrode.

6. The LED of claim 1, wherein at least one first extending portion and at least one second extending portion are provided on at lease one of the sidewalls of the base, the at least one first extending portion is electrically connected with a corresponding first branch portion, the at least one second extending portion is electrically connected with a corresponding second branch portion.

7. The LED of claim 1, wherein the base is made of light reflecting material.

8. The LED of claim 7, wherein the material of the base is chosen from a group consisting of epoxy resin, silicone, polyphthalamide.

9. A method for manufacturing LEDs, comprising steps:
providing a base plate having a plurality of first electrodes and a plurality of second electrodes spaced from the plurality of first electrodes, each of the first electrodes comprising a first main body portion and a plurality of first branch portions extending from the first main body portion, each of the second electrode comprising a second main body portion and a plurality of second branch portions extending from the second main body portion, at least one of the first branch portions of each first electrode and at least one of the second branch portions of a corresponding second electrode adjacent to each first electrode extending along two opposite directions, at least one of the first branch portions of each first electrode and at least one of the second branch portions of the corresponding adjacent second electrode extending along the same direction;
forming a substrate plate on the base plate;
providing a plurality of LED chips, two electrical contacts of an LED chip being electrically connected with each first electrode and the corresponding adjacent second electrode, respectively;
forming an encapsulant on each of LED chips, the encapsulant covering each of LED chips and each first electrode and the corresponding adjacent second electrode electrically connected with each of the LED chips; and
cutting the base plate and the substrate into a plurality of bases, each of the bases reserving each first electrode and the corresponding adjacent second electrode, the first branch portions of each first electrode and the second branch portions of the corresponding adjacent second electrode are exposed at sidewalls of each of the bases, at least one of the first branch portions and at least one of the second branch portions appearing at two opposite sidewalls of each of the bases, respectively, and at least another one the first branch portions and at least another one of the second branch portions appearing at the same sidewall of each of the bases.

10. The method of claim 9, wherein the first electrodes of the base plate are arranged in lines to form a plurality of first electrode columns, the second electrodes of the base plate are arranged in lines to form a plurality of second electrode columns, a number of the first electrode columns is equal to that of the first electrode columns, and the first electrode columns and the second electrode columns are spaced from each other and alternately arranged.

11. The method of claim 10, wherein the first main body portions of the first electrodes of each first electrode column are connected with each other through the first branch portions of the first electrodes, the second main body portions of the second electrodes of each second electrode column are connected with each other by the second branch portions of the second electrodes, the first electrodes of each first electrode column are spaced from the second electrodes of an adjacent second electrode column at one side of each first electrode column, and the first electrodes of each first electrode column are connected with the second electrodes of another adjacent second electrode column at an opposite side of each first electrode column through the first branch portions thereof.

12. The method of claim 11, wherein the step of cutting the base plate and the substrate comprising cutting the base plate and the substrate along widthwise direction and along lengthwise direction, the widthwise direction is perpendicular to the first/second electrode columns, the lengthwise direction is parallel to the first/second electrode columns, the first/second branch portions each connecting two adjacent first/second main body portions in each first/second electrode column are cut off during the widthwise cutting, each first electrode column and the adjacent second electrode column which originally connect with each other are separated from each other during the lengthwise cutting, each first electrode of the first electrode column and a corresponding second electrode of the another adjacent second electrode column which are originally spaced from each other are formed as two electrodes for a corresponding LED.

13. The method of claim 9, wherein the base plate is made of electrically conductive material, the first electrode and the second electrode are formed on the base plate through etching or stamping.

14. The method of claim 9, wherein the substrate plate is made of light reflecting material, and the substrate plate is formed on the base plate through molding.

15. The method of claim 9, wherein the material of the substrate plate is chosen from a group consisting of epoxy resin, silicone, polyphthalamide.

16. The method of claim 9, wherein the first main body portion of each of the first electrodes is exposed at two opposite sides of the substrate plate, the second main body portion of each of the second electrodes is exposed at two opposite sides of the substrate plate.

17. The method of claim 16, wherein each of the first branch portions of each first electrode is exposed at two opposite sides of the substrate plate, each of the second branch portions of each second electrode is exposed at two opposite sides of the substrate plate.

18. The method of claim 9, the substrate plate defines a plurality of recess corresponding to the LED chips, each of the recess spans the first main body portion of a first electrode and a second main body portion of an adjacent second electrode, each of the LED chips is received a corresponding recess.

19. The method of claim 9, further comprising a step for providing a first extending electrode at a free end of a first branch portion of each first electrode after the cutting step, and providing a second extending electrode at a free end of a second branch portion of each second electrode after the cutting step.
